(19) United States
(12) Patent Application Publication
(10) Pub. No.: US 2020/0025460 A1
(43) Pub. Date: Jan. 23, 2020

(54) HEAT SINK

(71) Applicant: FURUKAWA ELECTRIC CO., LTD., Tokyo (JP)

(72) Inventors: Hirofumi AOKI, Tokyo (JP); Yoshikatsu INAGAKI, Tokyo (JP); Kenya KAWABATA, Tokyo (JP); Hiroshi OKADA, Tokyo (JP); Daiki TAKEMURA, Tokyo (JP)

(73) Assignee: FURUKAWA ELECTRIC CO., LTD., Tokyo (JP)

(21) Appl. No.: 16/586,799

(22) Filed: Sep. 27, 2019

Related U.S. Application Data
(63) Continuation of application No. PCT/JP2018/013709, filed on Mar. 30, 2018.

(30) Foreign Application Priority Data
Mar. 31, 2017 (JP) 2017-070060

(51) Int. Cl. F28D 15/02

(52) U.S. Cl. CPC F28D 15/0275; H01L 23/427

(57) ABSTRACT

The present disclosure is related to providing a heat sink that exhibits an excellent cooling performance by preventing occurrence of a hot spot on a heat pipe. A heat sink comprising: a heat receiving plate to which a heating element is thermally connected; and a heat pipe thermally connected to the heat receiving plate, wherein a thermal conductivity of the heat receiving plate is higher than a thermal conductivity of a material of a container of the heat pipe.

### CROSS REFERENCE TO RELATED APPLICATIONS

The present application is a continuation application of International Patent Application No. PCT/JP2018/013709 filed on Mar. 30, 2018, which claims the benefit of Japanese Patent Application No. 2017-070060, filed on Mar. 31, 2017. The contents of these applications are incorporated herein by reference in their entirety.

### BACKGROUND

### Technical Field

The present disclosure relates to a heat sink that includes a heat receiving plate made of a material with a high thermal conductivity and thus can prevent occurrence of a hot spot on a heat pipe.

### Background

Electronic components, such semiconductor elements, mounted on electric and electronic devices tend to generate more heat for reasons such as high density mounting to provide high functionality, and cooling of these electronic components has been increasingly important in recent years. As a method for cooling a heating element such as the electronic components, a heat sink is used in some cases.

To efficiently cool the heating element, it is required to improve a heat radiation efficiency of the heat sink. In view of this, Japanese Patent Laid-Open No. 11-195738 proposes a heat sink that includes plural fins serving as a heat radiating portion vertically installed on a base portion serving as an attaching portion. In the heat sink, the fins and the base portion are integrally cast, and at least a part of a heat pipe is integrally cast in the base portion. In the heat sink of Japanese Patent Laid-Open No. 11-195738, the heat pipe is cast in the base portion made of metal, and this improves a thermal conductivity between the heat pipe and the base portion, as a result of which the heat radiation efficiency of the heat sink improves.

However, in the heat sink of Japanese Patent Laid-Open No. 11-195738, the heating element, which is an object to be cooled, is directly thermally connected to a container of the heat pipe, and thus a hot spot is likely to occur on the heat pipe with an increase in a thermal density of the heating element. This may result in a failure to ensure sufficient cooling properties.

### SUMMARY

The present disclosure is related to providing a heat sink that exhibits an excellent cooling performance by preventing occurrence of a hot spot on a heat pipe.

According to a first aspect of the present disclosure, a heat sink includes: a heat receiving plate to which a heating element is thermally connected; and a heat pipe thermally connected to the heat receiving plate, wherein a thermal conductivity of the heat receiving plate is higher than a thermal conductivity of a material of a container of the heat pipe.

In the first aspect, the heating element, which is an object to be cooled, is thermally connected to the heat receiving plate of the heat sink, and thereby the heating element is cooled. Heat of the heating element is transmitted from the heating element to the heat receiving plate, and the heat transmitted to the heat receiving plate is transmitted from the heat receiving plate to the heat pipe, and the heat transmitted to the heat pipe is released to an external environment of the heat sink by virtue of a heat transport function of the heat pipe. As a result of the heat of the heating element being released to the external environment via the heat receiving plate and the heat pipe, the heating element is cooled. In the first aspect, the heat pipe is thermally connected to the heating element via the heat receiving plate. Also, the heat pipe and the heat receiving plate are respectively made of materials with different thermal conductivities and are distinct members.

According to a second aspect of the present disclosure, in the heat sink, a part of an area of the container is thermally connected to the heat receiving plate. According to this aspect, the container of the heat pipe includes a portion not contacting the heat receiving plate and a portion contacting the heat receiving plate.

According to a third aspect of the present disclosure, in the heat sink, the thermal conductivity of the heat receiving plate is not less than 200 w/(m·k) and not more than 1500 w/(m·k), and the thermal conductivity of the material of the container is not less than 10 w/(m·k) and not more than 450 w/(m·k).

In the third aspect too, the heat receiving plate is made of a material having a higher thermal conductivity than a thermal conductivity of a material of the container of the heat pipe. In the present specification, the “thermal conductivity” refers to a thermal conductivity at 25 C°.

According to a fourth aspect of the present disclosure, in the heat sink, the material of the container comprises at least one kind selected from a group consisting of stainless steel, titanium, titanium alloy, aluminum, aluminum alloy, nickel, nickel alloy, iron, iron alloy, copper and copper alloy.

According to a fifth aspect of the present disclosure, in the heat sink, the heat receiving plate comprises at least one kind selected from a group consisting of copper, copper alloy, aluminum, aluminum alloy, silver, silver alloy, graphite and a carbon material.

According to a sixth aspect of the present disclosure, in the heat sink, a length of the heat receiving plate in a longitudinal direction is between 0.01 and 0.5 times a length of the container in the longitudinal direction.

According to a seventh aspect of the present disclosure, in the heat sink, a length of the heat receiving plate in a transverse direction is between 0.01 and 1.0 times a length of the container in the transverse direction.

According to an eighth aspect of the present disclosure, in the heat sink, an area of the heat receiving plate in plan view is between 0.005 and 1.0 times an area of the container in plan view.

In the present specification, the “plan view” refers to a view from the heat pipe side along a direction parallel to a heat transmission direction from the heat receiving plate to the heat pipe.

According to a ninth aspect of the present disclosure, in the heat sink, a thickness of the heat receiving plate is between 0.1 and 10.0 times a thickness of the container.

According to the embodiments of the heat sink in the present disclosure, the heat pipe is thermally connected to the heat receiving plate, and the thermal conductivity of the heat receiving plate is higher than the thermal conductivity of a material of the container of the heat pipe. As a result, heat transmitted from the heating element to the heat receiving plate spreads over the heat receiving plate before being transmitted to the heat pipe. This increases an effective area of an evaporation portion and prevents occurrence of a hot spot on the heat pipe. In other words, according to the embodiments in the present disclosure, heat is transmitted to the heat pipe with a thermal density being reduced by the heat receiving plate, and this prevents occurrence of a hot spot on the heat pipe. Thus, according to the embodiments of the heat sink in the present disclosure, the heat sink exhibits an excellent cooling performance because a thermal load on the heat pipe can be reduced. Also, according to the embodiments of the heat sink in the present disclosure, the heat receiving plate is disposed between the heat pipe and the heating element, and this prevents the heat pipe from locally contacting a part of the heating element (e.g. a peripheral portion of the heating element such as a corner portion) and deforming at the contact portion. When the heat pipe locally contacts the heating element and deforms at the contact portion, the deformed portion may locally receive heat to increase a thermal density, and thus a dry-out may occur in the heat pipe. However, as described above, in the heat sink of the present disclosure, the heat receiving plate prevents the heat pipe from locally deforming and locally contacting the heating element, and thus heat is transmitted from the heating element to the heat pipe with a thermal density being reduced. This prevents a dry-out of the heat pipe.

According to the embodiments of the heat sink in the present disclosure, a part of an area of the container is thermally connected to the heat receiving plate, and thereby heat diffusion properties of the heat receiving plate and the heat transport function of the heat pipe further improve. This allows for a further excellent cooling performance.

### BRIEF DESCRIPTION OF THE DRAWINGS

FIG. 1 is a plan view of a heat sink according to a first embodiment of the present disclosure.

FIG. 2 is a bottom view showing a state where a heating element is thermally connected to the heat sink according to the first embodiment of the present disclosure.

FIG. 3 is a partial cross-sectional side view of the heat sink according to the first embodiment of the present disclosure.

FIG. 4 is a plan view of the heat sink according to a second embodiment of the present disclosure.

FIG. 5 is a bottom view showing a state where the heating element is thermally connected to the heat sink according to a third embodiment of the present disclosure.

FIG. 6 is a bottom view showing a state where the heating element is thermally connected to the heat sink according to a fourth embodiment of the present disclosure.

FIG. 7 is a bottom view showing a state where the heating element is thermally connected to the heat sink according to a fifth embodiment of the present disclosure.

FIG. 8 is a graph showing results of Example and Comparative Examples.

### DETAILED DESCRIPTION

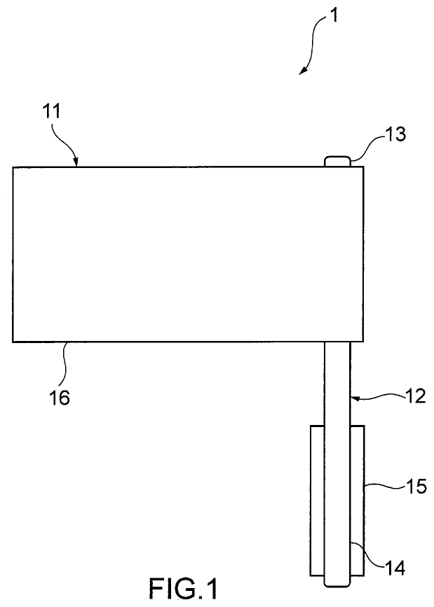

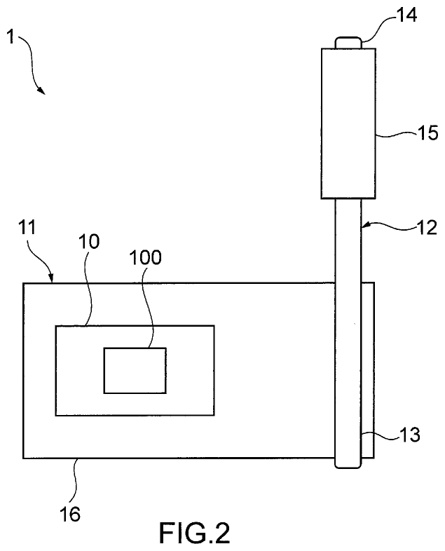

Hereinafter, a heat sink according to a first embodiment of the present disclosure will be described with reference to the accompanying drawings. As shown in FIGS. 1 and 2, the heat sink 1 according to the first embodiment includes a heat receiving plate 10, a first heat pipe 11 thermally connected to the heat receiving plate 10, a second heat pipe 12 thermally connected to the first heat pipe 11 at a part of one end portion 13, and heat radiating fins 15 thermally connected to another end portion 14 of the second heat pipe 12. A heating element 100 is cooled by the heat sink 1 by being thermally connected to the heat receiving plate 10.

A container 16 of the first heat pipe 11 has a flat plate shape. The flat plate-shaped container 16 is composed of a stack of one plate-shaped body and another plate-shaped body facing the one plate-shaped body. A central portion of the one plate-shaped body is plastically deformed into a protruding shape. The portion of the one plate-shaped body plastically deformed into the protruding shape defines a protruding part (not shown in the figure) of the container 16, and a hollow portion is defined inside the protruding part. An inner space of the hollow portion is depressurized by a deaeration treatment, and a working fluid (not shown in the figure) is enclosed in the inner space. Further, a wick structure (not shown in the figure) having a capillary force is provided inside the depressurized hollow portion. The first heat pipe 11, whose container 16 has the flat plate shape, is a planar heat pipe, and thus a vapor chamber.

The shape of the container 16 is not particularly limited, and in the first heat pipe 11, the container 16 has a rectangular shape in plan view (a shape as viewed from a vertical direction relative to a plane of the first heat pipe 11). The thickness of the container 16 is not particularly limited, and may be 0.3 mm to 1.0 mm, for example.

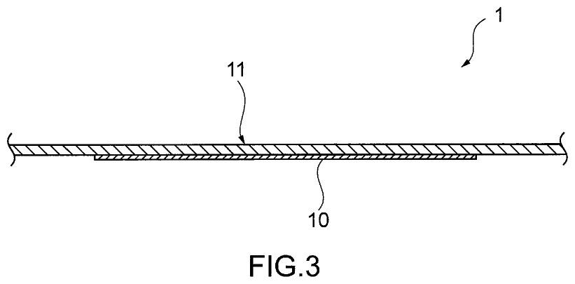

As shown in FIGS. 2 and 3, the heat receiving plate 10 in a flat plate shape is thermally connected to the container 16 of the first heat pipe 11. The shape of the heat receiving plate 10 in plan view is not particularly limited, and has a rectangular shape in the heat sink 1 as shown in FIG. 2. Further, the heat receiving plate 10 is attached to the container 16 such that a longitudinal direction of the heat receiving plate 10 and a longitudinal direction of the container 16 are substantially parallel to each other.

As shown in FIG. 2, in the heat sink 1, an entire one face of the heat receiving plate 10 in the flat plate shape is thermally connected to the container 16. In other words, the entire heat receiving plate 10 is provided at a position overlapping the container 16 of the first heat pipe 11 in plan view. On the other hand, the heating element 100, which is an object to be cooled, is thermally connected to another face of the heat receiving plate 10 in the flat plate shape. Accordingly, the heat receiving plate 10 is provided between the first heat pipe 11 and the heating element 100. An area of the container 16 in plan view (bottom view) is larger than an area of the heat receiving plate 10 in plan view (bottom view), and a part of the area of the container 16 in plan view (bottom view) is thermally connected to the heat receiving plate 10. In other words, the area of the heat receiving plate 10 in plan view (bottom view) is less than 1.0 times the area of the container 16 in plan view (bottom view). The area of the heat receiving plate 10 in plan view (bottom view) is not particularly limited, but is preferably between 0.005 and 1.0 times, and more preferably between 0.1 and 1.0 times the area of the container 16 in plan view (bottom view) in terms of ensuring heat diffusion properties of the heat receiving plate 10, and particularly preferably between 0.3 and 0.7 times the area of the container 16 in plan view (bottom view) in terms of improving both heat diffusion properties of the heat receiving plate 10 and the heat transport function of the first heat pipe 11 in a well-balanced manner.

As shown in FIGS. 2 and 3, in the heat sink 1, a length of the heat receiving plate 10 in the longitudinal direction is shorter than a length of the container 16 in the longitudinal direction. In other words, the length of the heat receiving plate 10 in the longitudinal direction is less than 1.0 times the length of the container 16 in the longitudinal direction. The length of the heat receiving plate 10 in the longitudinal direction is not particularly limited, and preferably between 0.01 and 1.0 times the length of the container 16 in the longitudinal direction in terms of ensuring heat diffusion properties of the heat receiving plate 10, and more preferably between 0.01 and 0.5 times, and particularly preferably between 0.1 and 0.5 times the length of the container 16 in the longitudinal direction in terms of improving both heat diffusion properties of the heat receiving plate 10 and the heat transport function of the first heat pipe 11 in a well-balanced manner. Note that the length of the heat receiving plate 10 in the longitudinal direction may be longer than the length of the container 16 in the longitudinal direction and, for example, the length of the heat receiving plate 10 in the longitudinal direction may be more than 1.0 to 2.0 times the length of the container 16 in the longitudinal direction.

In the heat sink 1, a length of the heat receiving plate 10 in a direction (transverse direction) perpendicular to the longitudinal direction is shorter than a length of the container 16 in a direction (transverse direction) perpendicular to the longitudinal direction in terms of improving both heat diffusion properties of the heat receiving plate 10 and the heat transport function of the first heat pipe 11 in a well-balanced manner. In other words, the length of the heat receiving plate 10 in the transverse direction is less than 1.0 times the length of the container 16 in the transverse direction. The length of the heat receiving plate 10 in the transverse direction is not particularly limited, and preferably between 0.01 and 1.0 times, and particularly preferably between 0.3 and 0.7 times the length of the container 16 in the transverse direction in terms of ensuring heat diffusion properties of the heat receiving plate 10.

The thickness of the heat receiving plate 10 is not particularly limited, and preferably between 0.1 and 10.0 times, more preferably between 0.1 and 5.0 times, and particularly preferably between 0.3 and 3.0 times a thickness of the container 16 in terms of a balance between heat diffusion properties and a thermal conductivity to the container 16.

The method for thermally connecting the container 16 and the heat receiving plate 10 is not particularly limited, and in the heat sink 1, a flat portion of the heat receiving plate 10 directly contacts a flat portion of the container 16, by which the container 16 (the first heat pipe 11) and the heat receiving plate 10 are thermally connected to each other. The method for joining and fixing the heat receiving plate 10 to the container 16 is not particularly limited, and examples may include screwing, soldering, brazing and welding.

Materials of the container 16 and the heat receiving plate 10 are not particularly limited as long as a thermal conductivity of a material of the heat receiving plate 10 is higher than a thermal conductivity of a material of the container 16. For example, the thermal conductivity of the heat receiving plate 10 is preferably not less than 200 w/(m·k) and not more than 1500 w/(m·k) at 25 C°, and particularly preferably not less than 300 w/(m·k) and not more than 450 w/(m·k) at 25 C°, in terms of ensuring heat diffusion properties of the heat receiving plate 10 and given the easy availability of the material. The thermal conductivity of the material of the container 16 is, for example, preferably not less than 10 w/(m·k) and not more than 450 w/(m·k) at 25 C°, more preferably not less than 10 w/(m·k) and less than 200 w/(m·k) at 25 C°, and particularly preferably not less than 10 w/(m·k) and not more than 100 w/(m·k), in terms of heat transmission to the container 16 with a thermal density being sufficiently reduced.

Examples of materials for the heat receiving plate 10 include copper, copper alloy, aluminum, aluminum alloy, silver, silver alloy, graphite (e.g. a graphite sheet) and a carbon material (e.g. a composite material using carbon fiber). Examples of materials for the container 16 include stainless steel, titanium, titanium alloy, aluminum, aluminum alloy, nickel, nickel alloy, iron, iron alloy, copper and copper alloy. However, since the thermal conductivity of a material of the heat receiving plate 10 is higher than the thermal conductivity of a material of the container 16, the container 16 is made of a material different from a material of the heat receiving plate 10.

Among the above materials, in terms of making the first heat pipe 11 light and thin while ensuring its mechanical strength and ensuring heat diffusion properties of the heat receiving plate 10, a combination of copper, copper alloy, aluminum or aluminum alloy for the heat receiving plate 10 and stainless steel, titanium or titanium alloy for the container 16 is preferable, and a combination of copper or copper alloy for the heat receiving plate 10 and stainless steel for the container 16 is particularly preferable. When the material of the heat receiving plate 10 is copper or copper alloy and the material of the container 16 is stainless steel, surface roughness (arithmetic average roughness: Ra) of copper or copper alloy is approximately 0.05 to 0.2 μm while surface roughness (Ra) of stainless steel is approximately 0.5 μm. That is, copper or copper alloy has a smaller surface roughness (Ra) than stainless steel. Accordingly, when the heat receiving plate 10 is thermally connected to the heating element 100 via thermally conductive grease (not shown in the figure), heat resistance between the heating element 100 and the heat sink 1 can be reduced as compared to a case where a heat pipe is thermally connected to the heating element 100 via thermally conductive grease without using the heat receiving plate 10.

Also, it is preferable that linear expansion coefficients of the container 16 and the heat receiving plate 10 be close to each other. With a difference in linear expansion coefficients, the container 16 is prone to separate from the heat receiving plate 10. Occurrence of this separation leads to increased heat resistance between the heat receiving plate 10 and the container 16. In terms of reliably preventing this separation by use of materials having comparable linear expansion coefficients, a combination of stainless steel for the container 16 and copper for the heat receiving plate 10 is particularly preferable.

The working fluid to be enclosed in the hollow portion of the container 16 may be selected as appropriate according to conformity with the material of the container 16, and examples include water. Examples further include CFC alternatives, fluorocarbons, cyclopentane, ethylene glycol and a mixture of water and any of these compounds. Also, examples of the wick structure include a sintered compact of copper powder or other metal powder, a metal mesh of metal wires, grooves and nonwoven fabric.

As shown in FIGS. 1 and 2, the second heat pipe 12 is thermally connected to an edge portion of the container 16 of the first heat pipe 11 in the longitudinal direction. A container of the second heat pipe 12 is a tubular body, and one end portion 13 of the container is thermally connected at the edge portion of the container 16 of the first heat pipe 11 in the longitudinal direction. The one end portion 13 extends over the entire transverse direction of the container 16. Further, the one end portion 13 extends along a plane of the container 16 of the first heat pipe 11. Accordingly, the second heat pipe 12 is thermally connected to the heat receiving plate 10 via the first heat pipe 11. The shape of the container of the second heat pipe 12 in a radial direction is not particularly limited, and examples include a round shape and an ellipse shape. Also, the container may have a flat shape formed by flattening the tubular body.

In the heat sink 1, a heat transport direction of the second heat pipe 12 is substantially in a parallel direction to the plane of the container 16 of the first heat pipe 11.

The material of the container of the second heat pipe 12 is not particularly limited, and examples include copper, copper alloy, aluminum, aluminum alloy, nickel, nickel alloy, stainless steel, titanium and titanium alloy. Examples of working fluids to be enclosed in the second heat pipe 12 include those mentioned for the first heat pipe 11. Further, examples of a wick structure to be stored inside the second heat pipe 12 include those mentioned for the first heat pipe 11. The method for joining the second heat pipe 12 to the first heat pipe 11 is not particularly limited, and examples include soldering, brazing and welding.

The other end portion 14 of the second heat pipe 12 is fitted with the heat radiating fins 15, which are thermally connected to the other end portion 14. Examples of materials for the heat radiating fins 15 include aluminum, aluminum alloy, copper and copper alloy.

Thereafter, functions of the heat sink 1 will be explained. When the heating element 100, which is an object to be cooled, is attached to the heat receiving plate 10 of the heat sink 1, heat of the heating element 100 is transmitted from the heating element 100 to the heat receiving plate 10. The heat transmitted to the heat receiving plate 10 is then transmitted from the heat receiving plate 10 to a heat receiving portion (a portion contacting the heat receiving plate 10) of the first heat pipe 11. The heat transmitted to the heat receiving portion of the first heat pipe 11 is then transported from the heat receiving portion of the first heat pipe 11 to a heat radiating portion that is a portion away from the heat receiving portion (in the heat sink 1, a portion where the one end portion 13 of the second heat pipe 12 is thermally connected), by virtue of the heat transport function of the first heat pipe 11. The heat is then transmitted from the heat radiating portion of the first heat pipe 11 to the one end portion 13 (a heat receiving portion) of the second heat pipe 12. The heat transmitted to the one end portion 13 of the second heat pipe 12 is then transported from the one end portion 13 to the other end portion 14 (a heat radiating portion) of the second heat pipe 12 by virtue of the heat transport function of the second heat pipe 12, and is further transmitted from the other end portion 14 to the heat radiating fins 15. The heat transmitted to the heat radiating fins 15 is released from the heat radiating fins 15 to an external environment of the heat sink 1. As a result of the heat of the heating element 100 being released from the heat radiating fins 15 to the external environment, the heating element 100 is cooled.

In the heat sink 1, the first heat pipe 11 is thermally connected to the heat receiving plate 10, and the thermal conductivity of the heat receiving plate 10 is higher than the thermal conductivity of the material of the container 16 of the first heat pipe 11. As a result, the heat transmitted from the heating element 100 to the heat receiving plate 10 preferentially spreads over the heat receiving plate 10 whose thermal conductivity is relatively high. After spreading over the heat receiving plate 10, the heat is then transmitted from the heat receiving plate 10 to the first heat pipe 11, and this can prevent occurrence of a hot spot on the first heat pipe 11. Thus, in the heat sink 1, a thermal load on the first heat pipe 11, which is thermally connected to the heating element 100 via the heat receiving plate 10, can be reduced, allowing the heat sink 1 to exhibit an excellent cooling performance. Also, when the first heat pipe 11 locally contacts the heating element 100 (e.g. contacts a peripheral portion of the heating element 100 such as a corner portion) and deforms at the contact portion, the deformed portion may locally receive heat from the heating element 100 to increase a thermal density, and thus a dry-out may occur in the first heat pipe 11. However, in the heat sink 1, the heat receiving plate 10 is disposed between the first heat pipe 11 and the heating element 100, and this can prevent the first heat pipe 11 from locally contacting a portion of the heating element 100 and deforming at the contact portion. In other words, the heat receiving plate 10 acts as a protection member for the first heat pipe 11. In this way, in the heat sink 1, deformation of the first heat pipe 11 at a local contact portion with the heating element 10 is prevented, and this allows heat to be transmitted from the heating element 100 to the first heat pipe 11 with a local increase in thermal density being prevented, which in turn prevents a dry-out of the first heat pipe 11.

Thereafter, a heat sink according to a second embodiment of the present disclosure will be described with reference to the drawings. The same components as those of the heat sink according to the first embodiment are explained with the same reference numerals.

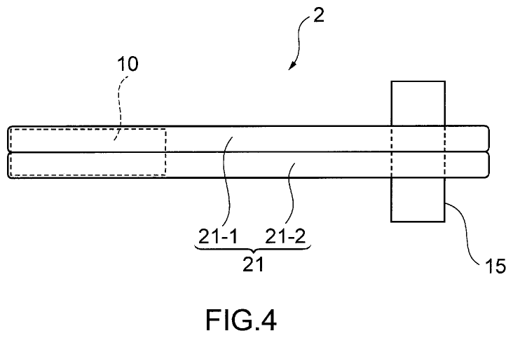

In the heat sink according to the first embodiment, the first heat pipe thermally connected to the heat receiving plate is a planar heat pipe, namely a vapor chamber, and the number of installed heat pipes is one. Instead of this, in the heat sink 2 according to the second embodiment, as shown in FIG. 4, a group of heat pipes that consists of plural (two in FIG. 4) flat heat pipes 21-1, 21-2 is used as a first heat pipe 21 thermally connected to the heat receiving plate 10. The two flat heat pipes 21-1, 21-2 have the substantially same shapes and dimensions, and are disposed in parallel to each other with sides contacting each other. The first heat pipe 21 thermally connected to the heat receiving plate 10 is thus formed.

For example, a container formed by flattening a tubular body having a round cross section in a radial direction is used for the flat heat pipes 21-1, 21-2.

In the heat sink 2 too, the length of the heat receiving plate 10 in the longitudinal direction is shorter than lengths of the flat heat pipes 21-1, 21-2 in the longitudinal direction. On the other hand, the length of the heat receiving plate 10 in a direction perpendicular to the longitudinal direction is substantially the same as a length of the first heat pipe 21 in the direction perpendicular to the longitudinal direction. In the heat sink 2, one end portions of the two flat heat pipes 21-1, 21-2 (i.e. one end portion of the first heat pipe 21) are thermally connected to the heat receiving plate 10 to function as a heat receiving portion, and other end portions that are opposite to the one end portions and not connected to the heat receiving plate 10 function as a heat radiating portion. The other end portion (heat radiating portion) of the first heat pipe 21 is fitted with the heat radiating fins 15.

In the heat sink 2, a second heat pipe thermally connected to the first heat pipe 21 is not provided.

In the heat sink 2 too, heat transmitted from the heating element (not shown in the figure) to the heat receiving plate 10 first spreads over the heat receiving plate 10, which has the relatively higher thermal conductivity than the container of the first heat pipe 21, before being transmitted to the flat heat pipes 21-1, 21-2. This can prevent occurrence of a hot spot on the flat heat pipes 21-1, 21-2.

Thereafter, a heat sink according to a third embodiment of the present disclosure will be described with reference to the drawings. The same components as those of the heat sink according to the first and the second embodiments are explained with the same reference numerals.

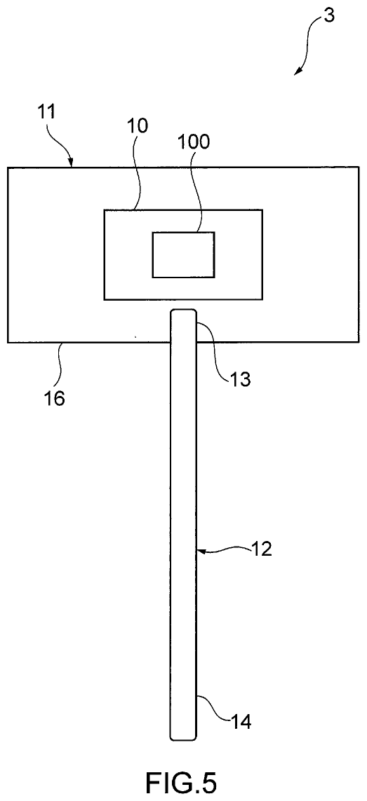

In the heat sink according to the first embodiment, the second heat pipe is thermally connected to the edge portion of the container of the first heat pipe in the longitudinal direction. Instead of this, in the heat sink 3 according to the third embodiment, as shown in FIG. 5, the second heat pipe 12 is thermally connected to an intermediate portion of the container 16 of the first heat pipe 11 in the longitudinal direction. The one end portion 13 of the second heat pipe 12 is thermally connected to the intermediate portion of the container 16 of the first heat pipe 11 in the longitudinal direction. Also, the one end portion 13 of the second heat pipe 12 is not extended to a central portion of the container 16 of the first heat pipe 11 but is thermally connected at a peripheral portion of the container 16 of the first heat pipe 11.

In the heat sink according to the first embodiment, the heat radiating fins are attached to the other end portion of the second heat pipe. However, in the heat sink 3 according to the third embodiment, no heat exchange means such as the heat radiating fins is attached to the other end portion 14 of the second heat pipe 12.

In the heat sink 3 too, the first heat pipe 11 is thermally connected to the heat receiving plate 10, and the thermal conductivity of the heat receiving plate 10 is higher than the thermal conductivity of the material of the container 16 of the first heat pipe 11. As a result, heat transmitted from the heating element 100 to the heat receiving plate 10 preferentially spreads over the heat receiving plate 10 whose thermal conductivity is relatively high. This can prevent occurrence of a hot spot on the first heat pipe 11. Thus, in the heat sink 3 too, a thermal load on the first heat pipe 11, which is thermally connected to the heating element 100 via the heat receiving plate 10, can be reduced, allowing the heat sink 3 to exhibit an excellent cooling performance.

Thereafter, a heat sink according to a fourth embodiment of the present disclosure will be described with reference to the drawings. The same components as those of the heat sink according to the first to the third embodiments are explained with the same reference numerals.

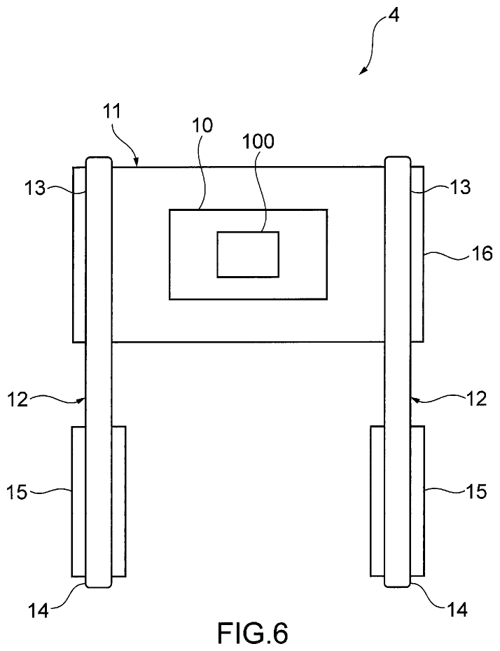

In the heat sink according to the first and the third embodiments, one second heat pipe is thermally connected to the container of one first heat pipe. Instead of this, in the heat sink 4 according to the fourth embodiment, as shown in FIG. 6, plural (two in FIG. 6) second heat pipes 12 are thermally connected to the container 16 of one first heat pipe 11. In the heat sink 4, the second heat pipes 12 are thermally connected to respective edge portions of the container 16 of the first heat pipe 11 in the longitudinal direction. The one end portions 13 of the respective second heat pipes 12 are thermally connected to the respective edge portions of the container 16 of the first heat pipe 11 in the longitudinal direction.

In the heat sink 4, the plural second heat pipes 12 are thermally connected to the first heat pipe 11, and this further improves a heat transport capability of the second heat pipe 12.

In the heat sink 4 too, the first heat pipe 11 is thermally connected to the heat receiving plate 10, and the thermal conductivity of the heat receiving plate 10 is higher than the thermal conductivity of the material of the container 16 of the first heat pipe 11. As a result, heat transmitted from the heating element 100 to the heat receiving plate 10 preferentially spreads over the heat receiving plate 10 whose thermal conductivity is relatively high. This can prevent occurrence of a hot spot on the first heat pipe 11. Thus, in the heat sink 4 too, a thermal load on the first heat pipe 11, which is thermally connected to the heating element 100 via the heat receiving plate 10, can be reduced, allowing the heat sink 4 to exhibit an excellent cooling performance.

Thereafter, a heat sink according to a fifth embodiment of the present disclosure will be described with reference to the drawings. The same components as those of the heat sink according to the first to the fourth embodiments are explained with the same reference numerals.

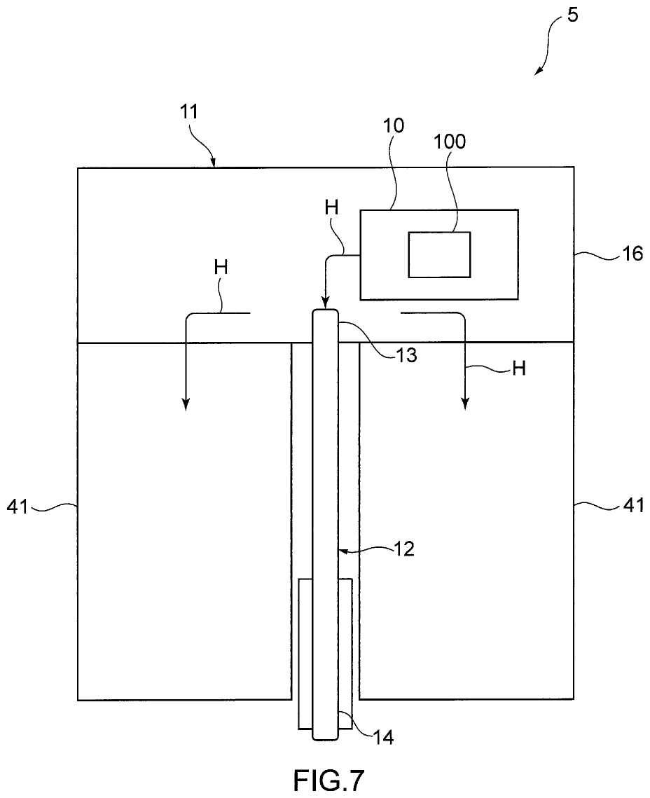

In the heat sink according to the first to the fourth embodiments, heat of the first heat pipe transmitted from the heating element is transmitted from the first heat pipe 11 to the second heat pipe. Instead of this, in the heat sink 5 according to the fifth embodiment, as shown in FIG. 7, heat H of the first heat pipe 11 transmitted from the heating element 100 is transmitted from the first heat pipe 11 not only to the second heat pipe 12 but also to thermally conductive members 41.

In the heat sink 5, not only the second heat pipe 12 but also the thermally conductive members 41 are thermally connected to the container 16 of the first heat pipe 11. In the heat sink 5, the second heat pipe 12 is thermally connected to an intermediate portion of the container 16 of the first heat pipe 11 in the longitudinal direction, and the thermally conductive members 41 are thermally connected adjacent to the second heat pipe 12. In FIG. 7, the thermally conductive members 41 are thermally connected to the container 16 of the first heat pipe 11 such that the thermally conductive members 41 are positioned at both sides of the second heat pipe 12. Further, the one end portion 13 of the second heat pipe 12 is not extended to a central portion of the container 16 of the first heat pipe 11 but is thermally connected at a peripheral portion of the container 16 of the first heat pipe 11.

Each of the thermally conductive members 41 is, for example, a plate-shaped or sheet-shaped member, and examples of materials for the thermally conductive members 41 include graphite and metals such as copper.

In the heat sink 5, not only the second heat pipe 12 but also the thermally conductive members 41 are thermally connected to the first heat pipe 11, and this further improves heat transmission properties from the first heat pipe 11. Further, in the heat sink 5, a thermal load not only on the first heat pipe 11 but also on the second heat pipe 12 can be reduced.

In the heat sink 5 too, the first heat pipe 11 is thermally connected to the heat receiving plate 10, and the thermal conductivity of the heat receiving plate 10 is higher than the thermal conductivity of the material of the container 16 of the first heat pipe 11. As a result, heat transmitted from the heating element 100 to the heat receiving plate 10 preferentially spreads over the heat receiving plate 10 whose thermal conductivity is relatively high. This can prevent occurrence of a hot spot on the first heat pipe 11. Thus, in the heat sink 5 too, a thermal load on the first heat pipe 11, which is thermally connected to the heating element 100 via the heat receiving plate 10, can be reduced, allowing the heat sink 5 to exhibit an excellent cooling performance.

Thereafter, alternative embodiments of the heat sink of the present disclosure will be described. In the heat sink according to the first and the third to the fifth embodiments, the second heat pipe is provided at an edge or intermediate portion (heat radiating portion) of the first heat pipe 1, which is thermally connected to the heat receiving plate, in the longitudinal direction. However, depending on usage conditions, the second heat pipe is not necessarily provided and the heat radiating fins may be provided to the first heat pipe. Also, in the heat sink according to the second embodiment, a second heat pipe may further be thermally connected to the flat heat pipes (the first heat pipe) thermally connected to the heat receiving plate, when necessary. In this case, the second heat pipe is thermally connected to the heat receiving plate via the flat heat pipes.

### Examples

Thereafter, Examples of the present disclosure will be described. The present disclosure is not limited to the Examples as long as the gist of the present disclosure is maintained.

As a heat sink, the heat sink according to the first embodiment as shown in FIGS. 1 to 3 was used.

The first heat pipe: a container made of stainless steel of 50 mm×100 mm×0.6 mm thickness, containing water as a working fluid.

The heat receiving plate: copper of 20 mm×30 mm×0.1 mm thickness (Example 1); stainless steel of 20 mm×30 mm×0.1 mm thickness (Comparative Example 2); no heat receiving plate in Comparative Example 1.

The second heat pipe: a flat container made of copper of ϕ6 mm×T 2 mm×L 100 mm, containing water as a working fluid.

The heat radiating fins: copper of 20 mm×10 mm×2 mm, the number of fins: twenty.

The heating element: 20 W.

Temperature was measured at four measurement points, namely (1) the heating element, (2) directly above the portion of the first heat pipe connected to the heating element, (3) the edge portion of the first heat pipe fitted with the second heat pipe, and (4) the other end portion of the second heat pipe. Temperature was measured by placing a thermocouple on a surface of each measurement point.

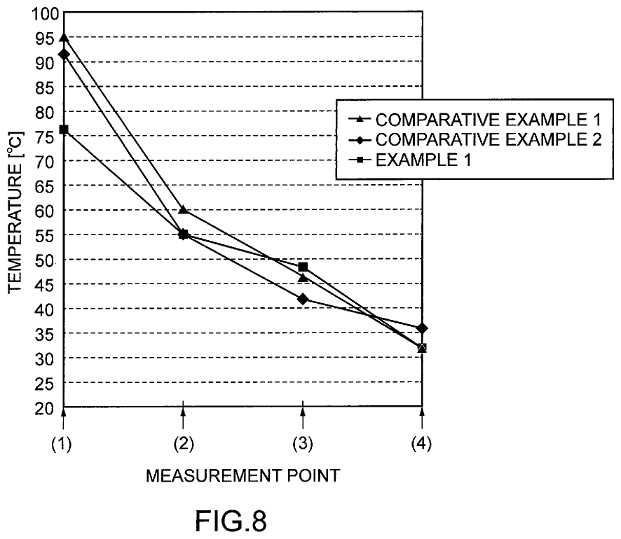

Results of Example 1 and Comparative Examples 1 and 2 are shown in FIG. 8. FIG. 8 shows that in Example 1, in which the container made of stainless steel and the heat receiving plate made of copper was used, temperature of the heating element was significantly reduced. On the other hand, in Comparative Example 1, in which the container made of stainless steel was used without providing the heat receiving plate, and in Comparative Example 2, in which the container made of stainless steel and the heat receiving plate made of stainless steel was used, the heating element was not sufficiently cooled.

The heat sink of the present disclosure can prevent occurrence a hot spot on the heat pipe and thus exhibit an excellent cooling performance even when an amount of heat from the heating element increases. Accordingly, the heat sink can be used in a variety of fields. For example, the heat sink has a high utility value particularly in the field of cooling of electronics components mounted on laptop personal computers, tablet personal computers and mobile electronic devices such as smartphones, which are mounted with electronic components generating a large amount of heat.

What is claimed is:

1. A heat sink comprising:
a heat receiving plate to which a heating element is thermally connected; and
a heat pipe thermally connected to the heat receiving plate, wherein
a thermal conductivity of the heat receiving plate is higher than a thermal conductivity of a material of a container of the heat pipe.

2. The heat sink according to claim 1, wherein a part of an area of the container is thermally connected to the heat receiving plate.

3. The heat sink according to claim 1, wherein the thermal conductivity of the heat receiving plate is not less than 200 w/(m·k) and not more than 1500 w/(m·k), and the thermal conductivity of the material of the container is not less than 10 w/(m·k) and not more than 450 w/(m·k).

4. The heat sink according to claim 1, wherein the material of the container comprises at least one kind selected from a group consisting of stainless steel, titanium, titanium alloy, aluminum, aluminum alloy, nickel, nickel alloy, iron, iron alloy, copper and copper alloy.

5. The heat sink according to claim 1, wherein the heat receiving plate comprises at least one kind selected from a group consisting of copper, copper alloy, aluminum, aluminum alloy, silver, silver alloy, graphite and a carbon material.

6. The heat sink according to claim 1, wherein a length of the heat receiving plate in a longitudinal direction is between 0.01 and 0.5 times a length of the container in the longitudinal direction.

7. The heat sink according to claim 1, wherein a length of the heat receiving plate in a transverse direction is between 0.01 and 1.0 times a length of the container in the transverse direction.

8. The heat sink according to claim 1, wherein an area of the heat receiving plate in plan view is between 0.005 and 1.0 times an area of the container in plan view.

9. The heat sink according to claim 1, wherein a thickness of the heat receiving plate is between 0.1 and 10.0 times a thickness of the container.
